(19) United States
(12) Patent Application Publication
(10) Pub. No.: US 2012/0326560 A1
(43) Pub. Date: Dec. 27, 2012

(54) WAFER LEVEL FABRICATION OF CAVITY FOR SURFACE ACOUSTIC WAVE FILTER

(75) Inventors: Hao Yun, Cary, NC (US); Richard A. Wessel, Raleigh, NC (US)

(73) Assignee: E. I. DU PONT DE NEMOURS AND COMPANY, Wilmington, DE (US)

(21) Appl. No.: 13/334,207

(22) Filed: Dec. 22, 2011

Related U.S. Application Data
(60) Provisional application No. 61/428,371, filed on Dec. 30, 2010.

(51) Int. Cl. H01L 41/053; H01L 41/22; B82Y 40/00

(52) U.S. Cl. 310/313 B; 427/100; 977/891

(57) ABSTRACT

This invention utilizes atomic layer deposition (ALD) to deposit a layer of a material (e.g., aluminum oxide) as a passivation and adhesion enhancement layer on a piezoelectric layer and an interdigitated transducer(s) (IDT(s)) of a surface acoustic wave (SAW) filter and also utilizes a photosensitive polymer layer (e.g., epoxy dry film) for photodefining a cavity for SAW filter fabrication. The ALD layer serves to protect the IDTs from possible corrosion caused by either the polymer layer and/or moisture and at same time provide for stable operation of the SAW filter without a signal shift occurring by protection of the piezoelectric layer. The cavity, having walls formed by the photosensitive polymer, provides for a SAW fabrication process that is simple and cost effective.

### FIELD OF THE INVENTION

This invention is in the field of surface acoustic wave (SAW) technology.

### BACKGROUND OF THE INVENTION

A surface acoustic wave (SAW) device normally includes a piezoelectric substrate with a transducer-mounting surface, and transmitting and receiving transducers formed on the transducer-mounting surface for transmitting and receiving surface waves propagating along the transducer-mounting surface of the substrate. Each of the transmitting and receiving transducers (which are frequently designated as IDTs (interdigitated transducers)) is in the form of a thin metal film. The SAW device is required to be enclosed within an enclosure so as to form an air cavity to permit propagation of surface acoustic wave(s) within the cavity. Due to the cavity required between the enclosure and the transducer-mounting surface of the substrate, the cavity has to be formed first and then the over mold can be applied to provide a full enclosure.

Traditionally, most portion(s) of a cavity for a surface acoustic wave (SAW) filter are fabricated using a ceramic type of material in order to provide a hermetical seal. SAW cavity fabrication processes using ceramic materials are typically complicated and costly. SAW cavity fabrication using polymeric material(s) has been tried but has heretofore not been successful due to the polymeric material(s) not providing a hermetical seal, such that moisture can get into the cavity. The presence of moisture in the SAW filter can cause an undesirable signal shift in operation of the SAW filter and may also cause corrosion on the input/output transducer or interdigitated tranducer (ITD) and piezoelectric substrate portion of the SAW filter.

A typical SAW filter can be fabricated by the following generalized process steps:

1) metallization of a piezoelectric substrate;

2) use of lithography to define a metal pattern, which includes application of photoresist, etching, and removal of photoresist;

3) create a cavity on the wafer using a photoresist to form roof and side walls of the cavity;

4) dice the wafer to afford individual SAW components;

5) make input/output connections; and

6) apply epoxy over a molder.

### SUMMARY OF THE INVENTION

In an embodiment, the invention is a method of protecting a piezoelectric surface and IDT(s) of a surface acoustic wave device, having an electrode system containing at least two metal electrodes, from corrosion and undergoing a frequency shift during operation, the method comprising a) applying a thin layer of a material by atomic layer deposition (ALD) to coat the piezoelectric surface of the acoustic wave device and IDT(s), wherein the thin layer of the material is a side of a cavity of the surface acoustic wave device.

In another embodiment, the invention is a surface acoustic wave device comprising:

a) a piezoelectric layer having a piezoelectric surface;

b) an IDT comprising at least two metal electrodes; and

c) a thin layer of a protective material deposited by atomic layer deposition on the piezoelectric layer. This surface acoustic wave device can be further comprised of a photoimaged polymer in contact with the thin layer of the protective material to form a cavity wherein the thin layer of the protective material defines a floor of the cavity of the surface acoustic wave device.

### BRIEF DESCRIPTION OF THE DRAWINGS

FIG. 1 illustrates a cross-sectional view of an embodiment of a SAW device according to the invention.

### DETAILED DESCRIPTION

As indicated above, an embodiment of the invention is a method of protecting IDTs on a piezoelectric surface(s) of a surface acoustic wave device from corrosion and undergoing a frequency shift. The method utilizes a protective layer of material applied by atomic layer deposition (ALD). Another embodiment is a surface acoustic wave device comprising a piezoelectric layer, an electrode system containing at least two electrodes on the piezoelectric layer, and a thin ALD layer.

The ALD material can be, but is not limited to, alumina. In various embodiments, the ALD layer can range from 5 nm (nanometers) to 50 nm, from 10 nm to 40 nm, and from 10 nm to 30 nm. In an embodiment, the ALD layer is about 20 nm. If the ALD layer is less than 5 nm, there may be pinholes in the ALD layer such that it does not provide sufficent protection from corrosion and shift in frequency with exposure to moisture. If the ALD layer is greater than 50 nm, there will likely be a detectable shift in frequency of the ALD-layer coated SAW device (compared to the uncoated device) that is undesirable in commercial production of SAW devices.

The piezoelectric layer and its associated surface may be, but are not limited to, lithium tantalate (LiTaO₃) or lithium niobate (LiNbO₃).

As an illustrative example of an embodiment, the following description is given: A photosensitive film (e.g., an epoxy dry film) is used to form a cavity for a SAW device by double lamination of epoxy dry film on an Al₂O₃ ALD (atomic layer deposition) passive layer bearing an IDT(s) on a surface acoustic device. To overcome the weak adhesion of epoxy on a SAW substrate such as lithium niobate or lithium tantalate, the ALD layer is applied over the SAW substrate (e.g, IDT on a piezoelectric layer) to enhance the adhesion of epoxy. The Al₂O₃ layer also serves as a passivation layer. In the fabrication process, first, a 20 nm thick Al₂O₃ layer is formed over the SAW substrate with build on the IDT piezoelectric substrate under low temperature so very low stress and pyro-electric is produced. The ALD layer covers all the area on the SAW substrate.

Then a first layer of epoxy dry film is laminated on the SAW substrate. A lithographic process is applied to define the cavity wall and connection pad. The epoxy film is cured at elevated temperature. At last, another layer of epoxy dry film is laminated on top of the walls to form the roof of the cavity. Since first layer is formed over the Al₂O₃ layer and adhesion between the epoxy with Al₂O₃ is higher, a suitably high level of adhesion is achieved. The potential corrosion of the IDT on the piezoelectric surface caused by the photosensitive epoxy is also eliminated by the Al₂O₃ ALD layer. Since the polymer cavity can not provide a perfect hermetical seal and there is always a chance that moisture can get into the polymer cavity, which will damper the SAW signal and cause a frequency shift. With this ALD layer (e.g., a Al2O3 layer as written above) protection, it will prevent the signal from shifting. This photoimaging process of forming a polymer cavity on a SAW filter is much simpler than the traditional ceramic cavity process. It can substantially reduce the cost of SAW filter fabrication.

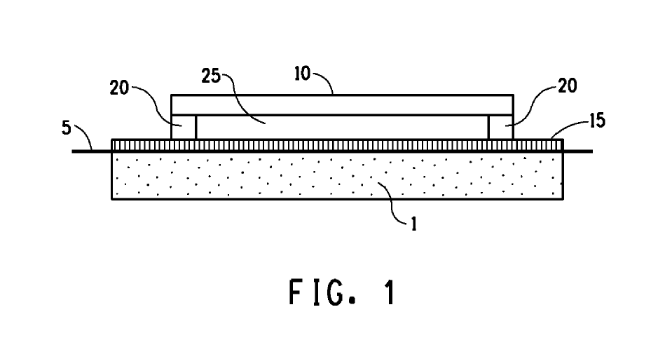

One embodiment of a SAW device according to the invention is illustrated in FIG. 1. In FIG. 1, 1 is a piezoelectric layer such as a lithium tantalite wafer. A metal electrode system containing at least two electrodes is shown as 5 in this figure. (One of the at least two electrodes is negative and the other is either positive or perhaps neutral.) An ALD layer (15), which can be amorphous alumina, is present above and in contact with the piezoelectric layer (1) and the metal electrode system (5). This layer 15 defines the floor of a cavity 25 of this SAW device. A layer 10 is the roof of the cavity 25 and layers 20 are sidewalls of the cavity 25. The sides 10 and 20 of the cavity can be photopolymerized and photoimaged photopolymer, such as photopolymerized epoxy dry film.

A SAW device usually requires the presence of an enclosed cavity in the device in order for there to be sufficiently effective transmission of surface acoustic waves from an input transducer(s) in the device to the output transducer(s) of the device. Without a cavity being present, the acoustic wave signal is significantly dampened and is usually not sufficient for the device to work properly.

### EXAMPLES

Deposition of an ALD Passivation Layer of Amorphous Alumina

In the examples below when utilized, the following procedure was used to deposit a layer of ALD amorphous alumina on lithium tantalate device wafers.

The wafers were coated in a Cambridge Nanotech Savannah reactor which was pumped with a mechanical pump to a background pressure of 0.15 Torr, in the presence of flowing inert nitrogen gas (20 sccm flow rate). The LiTaO3 device wafers were maintained at 100 degrees C. during the deposition. Trimethyaluminum (TMA) was used as the Al-precursor and H2O was used as the oxidant. (ALD is a sequential deposition method that deposits one atomic layer of Al2O3 in a single cycle. The film thickness is controlled by the number of repeated cycles.) The TMA and H2O precursors were unheated. In a single cycle, the LiTaO3 substrate was dosed with H2O for 30 milliseconds, followed by inert nitrogen gas purge of the reactor for 60 seconds; this was followed by a 30 millisecond dose with TMA and then a purge of the reactor with inert nitrogen gas for 30 seconds. This sequence of dose/purge/dose/purge was repeated 200 times. The Al2O3 film thickness, determined optically on a Si witness substrate was 20.1 nm, corresponding to an average deposition rate of 0.1 nm Al2O3 per ALD growth cycle.

### Example 1

In this example, the frequency response of a lithium tantalate (LiTaO₃) device wafer (having 5 ILDs on its surface) without a passivation layer of ALD (atomic layer deposition) alumina was measured and compared to an otherwise identical lithium tantalate (LiTaO₃) wafer having a passivation layer of ALD alumina. In each case, the amplitude (signal strength) was measured and recorded in decibels (db) versus frequency in megahertrz (Mhz) over the range from 1700-3300 megahertz. The thickness of the passivation layer of ALD alumina , which was amorphous alumina, was 20 nanometers. The two amplitude versus frequency recordings were essentially identical based upon visual observation. This finding is important with regard to use of such an ALD layer to passivate and protect an underlying piezoelectric layer (e.g., this lithium tantalate wafer) bearing ILDs in a SAW (surface acoustic wave) device since device manufactures do not want any shift in frequency to occur due to the presence of the passivation layer.

### Example 2

This example illustrates that a device wafer bearing ILDs that is passivated with an ALD layer does not exhibit corrosion on the ILD surfaces when immersed in water for a period of time. A lithium tantalate device wafer having 5 ILDs on its surface was subjected to ALD treatment as detailed in Example 1 to deposit a 20 nm layer of ALD amorphous alumina on its surfaces. The resulting passivated device wafer was then immersed in tap water for 48 hours at ambient temperature. This device wafer did not exhibit any visible corrosion of the ILD surfaces after being submerged in tap water for 48 hours (from observation by one's naked eyes of optical microscopy photographs).

### Example 3 (Comparative)

This comparative example illustrates that a device wafer bearing ILDs that is not passivated with an ALD layer does exhibit corrosion on the ILD surfaces when immersed in water for a period of time. A lithium tantalate device wafer that was identical to the wafer of Example 2 (prior to ALD treatment for passivation) having 5 ILDs on its surface was immersed in tap water for 48 hours at ambient temperature. This device wafer did exhibit extensive corrosion (from observation by one's naked eyes of optical microscopy photographs) of all of the ILD surfaces after having been submerged in tap water for 48 hours.

### Example 4 (Prophetic)

The device wafer of Example 2, after having been submerged in tap water at ambient temperature for 48 hours, is dried and subjected to frequency response testing (as detailed in Example 1) to determine if there is any change in frequency response. It is believed by the inventors that there will be little or no change in frequency response that is measured.

### Example 5 (Prophetic and Comparative)

The device wafer of Example 3, after having been submerged in tap water at ambient temperature for 48 hours, is dried and subjected to frequency response testing (as detailed in Example 1) to determine if there is any change in frequency response. It is believed by the inventors that there will be a very significant change in frequency response that is measured for this bare (not passivated) device wafer.

What is claimed is:

1. A method of protecting an IDT and a piezoelectric surface of a surface acoustic wave device having an electrode system containing at least two metal electrodes from corrosion and undergoing a frequency shift during operation, the method comprising a) applying a thin layer of a material by atomic layer deposition to coat the piezoelectric surface of the acoustic wave device and the electrode system, wherein the thin layer of the material is a side of a cavity of the surface acoustic wave device.

2. The method of claim 1 wherein the thin layer of the material is alumina.

3. The method of claim 1 wherein the piezoelectric surface comprises lithium tantalate or lithium niobate.

4. The method of claim 1 wherein the thin layer of the material ranges from 5 nanometers to 50 nanometers.

5. A surface acoustic wave device comprising:
a) a piezoelectric layer having a piezoelectric surface;
b) an IDT comprising at least two metal electrodes; and
c) a thin layer of a protective material deposited by atomic layer deposition on the piezoelectric surface.

6. The surface acoustic wave device of claim 5 further comprising a photoimaged polymer in contact with the thin layer of the protective material to form a cavity wherein the thin layer of the protective material defines a floor of the cavity of the surface acoustic wave device.

7. The surface acoustic wave device of claim 5 wherein the protective material is alumina (Al₂O₃).

8. The surface acoustic wave device of claim 5 wherein the piezoelectric layer comprises lithium tantalate or lithium niobate.

9. The surface acoustic wave device of claim 5 wherein the protective material has a thickness ranging from 5 nanometers to 50 nanometers.
